(19) United States
(12) Patent Application Publication
(10) Pub. No.: US 2020/0181754 A1
(43) Pub. Date: Jun. 11, 2020

(54) A MASK AND A MASK DEVICE USING THE SAME

(71) Applicant: Wuhan China Star Optoelectronics Semiconductor Display Technology Co., Ltd., Wuhan, Hubei (CN)

(72) Inventor: Jian YE, Wuhan, Hubei (CN)

(21) Appl. No.: 16/341,909

(22) PCT Filed: Mar. 19, 2019
(86) PCT No.: PCT/CN2019/078684

§ 371 Date: Apr. 14, 2019

(30) Foreign Application Priority Data
Dec. 11, 2018 (CN) 201811511453.5

(51) Int. Cl. C23C 14/04; C23C 14/24

(52) U.S. Cl. CPC C23C 14/042; C23C 14/24

(57) ABSTRACT

The present invention provides a mask and a mask device using the same. The advantage of the present invention is that, buffer zones at both ends of an existing mask are set as an effective evaporation zone, which can be used to make a Mini display panel with pixels of a low density, so it not only can be used as one deformation buffer zone, but also can be used as one effective opening zone applied to a display panel with pixels of a low density, thereby effectively improving the utilization efficiency of the mask.

### BACKGROUND OF THE INVENTION

### 1. Field of the Invention

The present invention relates to a technology of display devices, and more particularly to a mask and a mask device using the same.

### 2. Description of the Prior Art

Recently, with the development of smart terminal devices and wearable devices, the demand for a flat panel display becomes more and more diverse. For example, an OLED (Organic Light-Emitting Diode) display is more and more popular in the market because of its advantages of active luminescence, large visual angle, wide gamut, high brightness and fast response speed. At the same time, people's demand for a full screen is becoming more and more urgent. That is, a screen occupation rate of the whole smart phone is becoming higher and higher. Specifically, a length-width ratio of the screen of the phone has increased from 16:9 to 18:9 and 18.5:9, even to 19.5:9 [symbol] 20:9 and so on.

At present, the most common method to fabricate an OLED is vacuum evaporation. Organic light-emitting materials are heated in a crucible, change from solid to gaseous, pass through openings of a FMM (Fine Metal Mask), and then are deposited in a corresponding PDL (Pixel Definition Layer) on a TFT array substrate. The openings of the fine metal mask are corresponding to R/G/B sub-pixels one by one. When a certain color is evaporated, the fine metal mask corresponding to that color can be used.

The fine metal mask is an important bottleneck technology which restricts the development of high resolution OLED display. At present, a wet etching is a main method to produce the fine metal mask in mass production. Specifically, first of all, a tooling with a pattern of specific openings is made, that is, the photo mask. Then, the corresponding openings are etched on the metal film material by yellow photolithography technology, and the corresponding fine metal mask is made.

### 3. Technical Problem

FIG. 1 is a top plan schematic view of an existing fine metal mask. Please refer to FIG. 1, the fine metal mask includes multiple effective evaporation zones A (zones circled by rectangular dotted frames in FIG. 1), and multiple buffer zones B (zones circled by elliptical dashed boxes in FIG. 1). Some of the buffer zones B are disposed between the effective evaporation zones A and the others thereof are disposed on a periphery of the effective evaporation zones A. Each effective evaporation zone A has multiple first openings 10, which are corresponding to positions of the pixels on the array substrate that needs to be evaporated one by one, thereby evaporating the organic light-emitting material with corresponding color at the position of the pixels. Each buffer zone B has multiple second openings, which play an anti-deformation role in a subsequent tension process and can ensure that the first openings of the fine metal mask are corresponding to the pixels positions on the array substrate one by one and no offset occurs.

The disadvantages of the existing fine metal mask is that, the buffer zones B can not be used as effective evaporations and reduce the area of the effective evaporation zones of the fine metal mask, so the space utilization rate of the fine metal mask is not high. Further, one type of fine metal mask can only be used on the same type of panel, so this will also make the fine metal mask less compatible. Moreover, the production cost of fine metal mask is usually relatively expensive and high, so this will lead to higher cost of fine metal mask and further lead to higher production cost of display panel.

### BRIEF SUMMARY OF THE INVENTION

### Technical Solutions

The technical problems to be solved by the present invention are to provide a mask and a mask device using the same to effectively improve the utilization efficiency of the mask.

For solving above problems, the present invention provides a mask, which comprises multiple first opening zones, at least one second opening zone and a frame enclosing the first opening zones and the second opening zone. In a first direction, the second opening zone is disposed on at least one end of the first opening zones. Each first opening zone includes at least one first evaporation zone, and the second opening zone includes at least one second evaporation zone. The first evaporation zone has multiple first openings, the second evaporation zone has multiple second openings, and a density of the multiple first openings is greater than that of the multiple second openings. The first opening zone further includes a first buffer zone surrounding the first evaporation zone, and the second opening zone further includes a second buffer zone surrounding the second evaporation zone. The first buffer zone has multiple third openings, which are all-etched or semi-etched. The second buffer zone has multiple fourth openings, which are all-etched or semi-etched. The mask disposes one unetched zone between the first opening zone and the second opening zone, and further disposes one unetched zone between each two adjacent first opening zones.

In one embodiment, the mask includes two second opening zones, in the first direction, the two second opening zones are disposed on two ends of the multiple first opening zones.

In one embodiment, the second opening zone includes multiple second evaporation zones, and the second buffer zone surrounds the multiple second evaporation zones.

For solving above problems, the present invention further provides a mask, comprising at least one first opening zone, at least one second opening zone and a frame enclosing the first opening zone and the second opening zone. In a first direction, the second opening zone is disposed on at least one end of the first opening zone. The first opening zone includes at least one first evaporation zone, and the second opening zone includes at least one second evaporation zone. The first evaporation zone has multiple first openings, the second evaporation zone has multiple second openings, and a density of the multiple first openings is greater than that of the multiple second openings.

In one embodiment, the mask comprises multiple first opening zones and two second opening zones, in the first direction, the two second opening zones are disposed on two ends of the multiple first opening zones.

In one embodiment, the frame has a connection zone connected with an external device, and the second opening zone is located between the connection zone and the first opening zone.

In one embodiment, the first opening zone further includes a first buffer zone surrounding the first evaporation zone, and the second opening zone further includes a second buffer zone surrounding the second evaporation zone.

In one embodiment, the second opening zone includes multiple second evaporation zones, and the second buffer zone surrounds the multiple second evaporation zones.

In one embodiment, the first buffer zone has multiple third openings, which are all-etched or semi-etched; and the second buffer zone has multiple fourth openings, which are all-etched or semi-etched.

In one embodiment, the mask disposes one unetched zone between the first opening zone and the second opening zone; the mask further includes multiple first opening zones, and disposes one unetched zone between each two adjacent first opening zones.

The present invention further provides a mask device, comprising an external framework having a hollow workspace; at least one mask as described above, in the first direction, two ends of the frame being connected with the external framework; at least one support bar being disposed in the workspace; in a second direction, two ends of the support bar being connected with the external framework for supporting the mask; and at least one shadow bar being disposed in the workspace and being corresponding to a gap between the mask and the external framework for shading the gap; in the first direction, two ends of the shadow bar being connected with the external framework; the support bar and the shadow bar intersecting to form a plurality of display limiting areas; the first opening zone and the second opening zone of the mask being corresponding to at least one display limiting area.

In one embodiment, the mask device includes multiple masks and multiple shadow bars, and at least one shadow bar is corresponding to a gap between two adjacent masks for shading the gap.

In one embodiment, the mask includes multiple first opening zones and multiple support bars; at least one support bar is corresponding to a gap between the first opening zone and the second opening zone, and at least another support bar is corresponding to a gap between two adjacent first opening zones.

### Beneficial Effect

The advantage of the present invention is that, the buffer zones B at both ends of the existing mask are set as an effective evaporation zone, which can be used to make a Mini display panel with pixels of a low density, so it not only can be used as one deformation buffer zone, but also can be used as one effective opening zone applied to a display panel with pixels of a low density, thereby effectively improving the utilization efficiency of the mask. Moreover, when stretching the mask, the displacement of the openings in a middle of the mask is smaller than that of the openings in an edge of the mask. Therefore, by appropriately reducing the density of the openings at the edge of the mask, the problem of poor alignment accuracy between the openings at the edge and the openings at a passivation dielectric layer (PDL) of the array substrate when stretching the mask can be avoided.

### BRIEF DESCRIPTION OF THE DRAWINGS

FIG. 1 is a top plan schematic view of an existing fine metal mask;

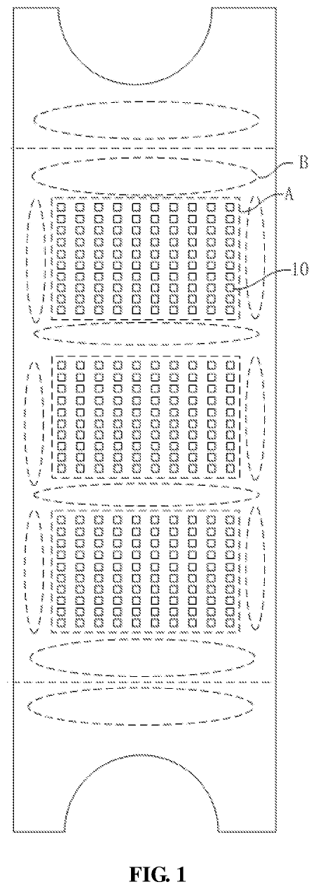

FIG. 2 is a top plan schematic view of one embodiment of a mask of the present invention;

FIG. 3 is a top plan schematic view of another embodiment of the mask of the present invention;

FIG. 4 is a top plan schematic view of another embodiment of the mask of the present invention; and

FIG. 5 is a structure schematic view of one embodiment of a mask device of the present invention.

### DETAILED DESCRIPTION OF THE PREFERRED EMBODIMENTS

Following is a detailed description of the specific implementations of a mask provided by the present invention and a method of fabricating a display panel using the mask in conjunction with the accompanying drawings.

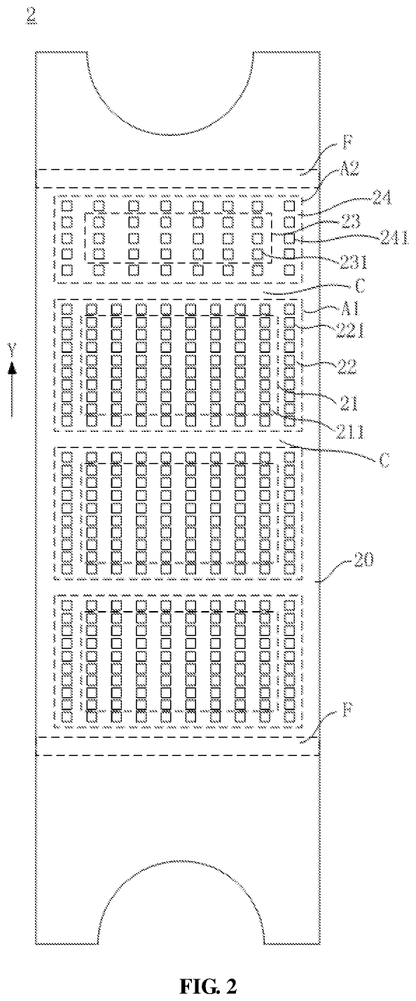

FIG. 2 is a top plan schematic view of one embodiment of a mask of the present invention. Please refer to FIG. 2, the mask 2 of the present invention includes at least one first opening zone A1, at least one second opening zone A2, and a frame 20 enclosing the first opening zone A1 and the second opening zone A2.

The frame 20 is a support framework of the mask 2. The frame 20 can be a metal frame. A method of fabricating the mask 2 can adopt a conventional etching process. For example, providing a thin sheet metal; overshadowing the thin sheet metal by a tooling with a special pattern, etching the thin sheet metal by an etching solution, forming the first opening zone A1 and the second opening zone A2, and finally obtaining the mask 2. Wherein, an unetched part located outside the first opening zone and the second opening zone is the frame 20.

The mask 2 includes one or multiple first opening zones A1. In the embodiment, in order to clearly illustrate the technical scheme of the present invention, only three first opening zones A1 are schematically drew. In other embodiments, the number of the first opening zones A1 can be determined according to the size and the number of the display panel to be fabricated. In the embodiment, there is one unetched zone C between each two adjacent first opening zones A1, thereby increasing the strength of the mask 2. Wherein, the unetched zones C refer to the zones, which are not etched or semi-etched. For example, there is an all-metal zone between each two adjacent first opening zones A1, and this zone is one unetched zone C.

Each first opening zone A1 includes at least one first evaporation zone 21. In the embodiment, each first opening zone A1 includes one first evaporation zone 21. But in other embodiments, each first opening zone A1 may include multiple first evaporation zones 21.

The first evaporation zone 21 has multiple first openings 211. The first opening 211 is a through hole through the mask 2. The cross section shape, size and quantity of the first opening 211 are conventional designs in the field, and the shape of the cross section includes, but is not limited to conventional shape such as circular, rectangular and so on. In the drawings of the present invention, the first opening 211 is schematically depicted. The present invention does not limit specific parameters of the first opening 211 as long as it can satisfy the purpose of the invention. When the mask of the present invention is used for evaporation plating, one first evaporation zone 21 is corresponding to a pixel-limited zone of one array substrate (not shown in the drawing), and the first openings 211 are corresponding to pixel positions that needs to be evaporated with the organic light-emitting material. The multiple first evaporation zones 21 are corresponding to pixel-limited zones of multiple array substrates.

Further, the first opening zone A1 also includes a first buffer zone 22 surrounding the first evaporation zone 21. Specifically, the first buffer zone 22 is arranged around the first evaporation zone 21. In a subsequent tension process, the first buffer zone 22 provides an anti-deformation function and ensures that the first openings 211 of the first evaporation zone 21 are corresponding to pixel positions on the array substrate one by one and no offset occurs. Wherein, the first buffer zone 22 has multiple third openings 221, which are all-etched or semi-etched. Because the first buffer zone 22 is not an effective zone for evaporating organic materials, the third openings 221 of the first buffer zone 22 may be all-etched openings, or may be semi-etched openings. The all-etched openings mean that the third openings 221 pass through the mask 2, and the semi-etched openings mean that the third openings 221 do not pass through the mask 2. The shape and size of the third opening 221 can be the same as or different from those of the first opening 211, namely this is not limited in the present invention. The cross section shape, size and quantity of the third opening 211 are common designs for this field. The cross section shape includes, but is not limited to conventional shape such as circular, rectangular and so on. The drawings of the present invention only schematically illustrate the third openings 221, and specific parameters of the third openings 221 are not limited as long as it can satisfy the purposes of the present invention.

In a first direction (as shown by Y arrow in the figure), the second opening zone A2 is disposed on at least one end of the first opening zone A1. Specifically, the second opening zone A2 is disposed on at least one end of the mask 2, but not between any two of the first opening zones A1.

For example, in the embodiment, the mask 2 includes three first opening zones A1 and one second opening zone A2. The second opening zone A2 and the three first opening zones A1 are arranged in sequence from bottom to top along the first direction. Wherein, the second opening zone A2 is located on a top of the mask 2, but not between any two of the first opening zones A1. In the embodiment, the first direction refers to the Y direction. In other embodiments, the first direction may be other directions.

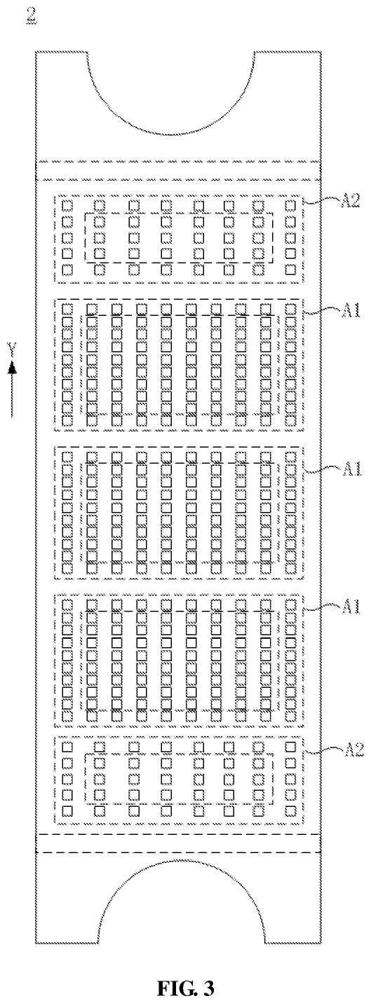

In another embodiment of the mask of the present invention, please refer to FIG. 3, the mask 3 includes three first opening zones A1 and two second opening zones A2. In the first direction, one second opening zone A2, the three first opening zones A1 and the other second opening zone A2 are arranged in sequence from bottom to top along the first direction. Wherein, the two second opening zones A2 are respectively located on a top and a bottom of the mask 2, but not between any two of the first opening zones A1.

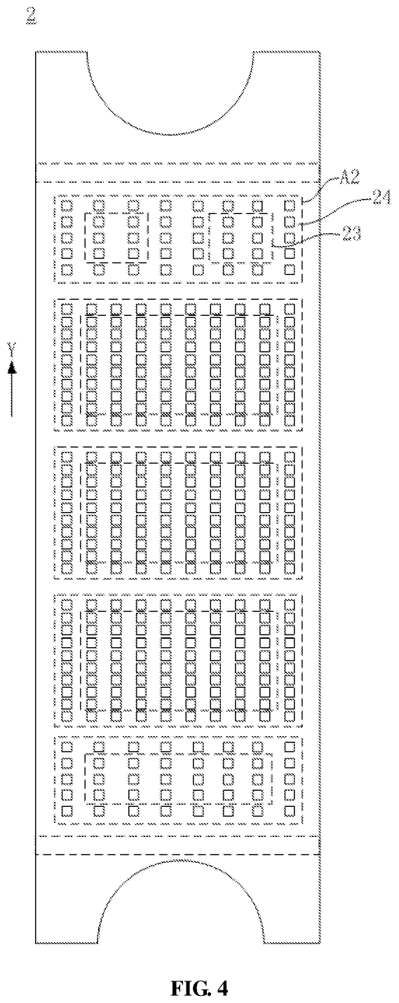

Please refer to FIG. 2, each second opening zone A2 includes at least one second evaporation zone 23. In the embodiment, each second opening zone A2 includes one second evaporation zone 23. In other embodiments, each second opening zone A2 may include multiple second evaporation zones 23. Please refer to FIG. 4, in another embodiment of the mask of the present invention, each second opening zone A2 includes two second evaporation zones 23.

The second evaporation zone 23 has multiple second openings 231. The second opening 231 is a through hole through the mask 2. The cross section shape, size and quantity of the second opening 231 are conventional designs in the field, and the shape of the cross section includes, but is not limited to conventional shape such as circular, rectangular and so on. The present invention does not limit specific parameters of the second opening 231 as long as it can satisfy the purpose of the invention. When the mask of the present invention is used for evaporation plating, one second evaporation zone 23 is corresponding to a pixel-limited zone of one array substrate (not shown in the drawing), and the second openings 231 are corresponding to pixel positions that needs to be evaporated with the organic light-emitting material. The multiple second evaporation zones 23 are corresponding to pixel-limited zones of multiple array substrates.

The density of the first openings 211 is greater than that of the second openings 231. Specifically, in the array substrate, pixels corresponding to the first evaporation zone 21 have a high density, and pixels corresponding to the second evaporation zone 22 have a low density. The mask of the invention also sets the buffer zones B at both ends of the existing mask as an effective evaporation zone, which can be used to make a Mini display panel with pixels of a low density. The advantages of the present invention are that, the second opening zone A2 not only can be used as one deformation buffer zone of the first opening zone A1, but also can be used as one effective opening zone applied to a display panel with pixels of a low density, thereby effectively improving the utilization efficiency of the mask. Moreover, during the tension process of the mask 2, the displacement of the openings in a middle of the mask 2 (namely in the first opening zone A1) is smaller than that of the openings in an edge of the mask 2 (namely in the second opening zone A2). Therefore, by appropriately reducing the density of the openings at the edge of the mask 2, the problem of poor alignment accuracy between the openings at the edge and the openings at a passivation dielectric layer (PDL) of the array substrate can be avoided.

Further, the second opening zone A2 also includes a second buffer zone 24 surrounding the second evaporation zone 23. Specifically, the second buffer zone 24 is arranged around the second evaporation zone 23. In a subsequent tension process, the second buffer zone 24 provides an anti-deformation function and ensures that the second openings 231 of the second evaporation zone 23 are corresponding to pixel positions on the array substrate one by one and no offset occurs. Wherein, the second buffer zone 24 has multiple fourth openings 241, which are all-etched or semi-etched. Because the second buffer zone 24 is not an effective zone for evaporating organic materials, the fourth openings 241 of the second buffer zone 24 may be all-etched openings or semi-etched openings. The all-etched openings mean that the fourth openings 241 pass through the mask 2, and the semi-etched openings mean that the fourth openings 241 do not pass through the mask 2. The shape and size of the fourth opening 241 can be the same as or different from those of the second opening 231, namely this is not limited in the present invention. The cross section shape, size and quantity of the fourth opening 241 are common designs for this field. The cross section shape includes, but is not limited to conventional shape such as circular, rectangular and so on. Specific parameters of the fourth openings 241 are not limited as long as it can satisfy the purposes of the present invention. Referring to FIG. 4, in another embodiment of the mask of the present invention, each second evaporation zone 23 is surrounded by the second buffer zone 24.

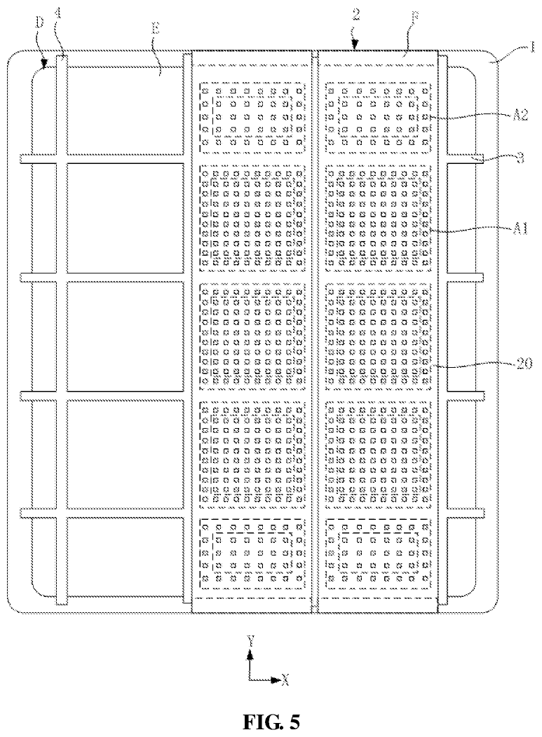

Please continue to refer to FIG. 2, the frame 20 has a connection zone F connected with an external device (an external framework 1 as shown in FIG. 5). The second opening zone A2 is located between the connection zone F and the first opening zone A1. Namely, the second opening zone A2 is disposed on one end or two ends of the mask 2, but not between any two of the first opening zones A1.

Further, there is also one unetched zone C between the first opening zone A1 and the second opening zone A2 for further increasing the strength of the mask 2.

The present invention further provides a mask device. FIG. 5 is a structure schematic view of one embodiment of the mask device of the present invention. Please refer to FIG. 5, the mask device includes an external framework 1, at least one above mask 2, at least one support bar 3 and at least one shadow bar 4.

The external framework 1 has a hollow workspace D. Specifically, the external framework 1 is hollow in the middle and can be used to support the mask 2, the support bar 3 and the shadow bar 4. A hollow part in the middle of the external framework 1 is the workspace D. The shape of the external framework 1 includes, but not is limited to rectangular, circular, etc. Personnel skilled in the field may set it according to their specific use.

In a first direction (as shown by Y arrow in the figure), two ends of the frame are connected with the external framework 1. Specifically, the connection zone F on the two ends of the frame 20 is fixed on the external framework 1 by welding or other ways. In the embodiment, in order to clearly describe the technical scheme of the present invention, only two masks 2 are schematically depicted. After the mask 2 is connected to the external framework 1, parts located outside the connection zone F of the mask 2 can be removed for avoiding affecting the operation of the mask device.

The support par 3 is disposed in the workspace D and located below the mask 2. The support par 3 is not right under the mask 2, and here is just a description of the relative relationship between two planes where the both are located respectively. Namely, one plane, where the support bar 3 is located, is below the other plane, where the mask 2 is located. In the embodiment, in order to clearly describe the technical scheme of the present invention, only four support bars 3 are schematically depicted, and the four support bars 3 are parallel.

In a second direction, two ends of the support bar 3 are connected with the external framework 1 to support the mask 2 and prevent the mask 2 from sagging. Specifically, in the embodiment, the two ends of the support bar 3 are fixed on the external framework 1 by welding. In other embodiments of the present invention, the two ends of the support bar 3 can also be fixed on the external framework 1 by other ways. For example, the two ends of the support bar 3 can be fixed on the external framework 1 by screw. Wherein, the first direction is at an angle with the second direction. In the embodiment, the first direction is perpendicular to the second direction. The first direction refers to Y direction, and the second direction refers to X direction. That is to say, in the embodiment, the support bar 3 is perpendicular to the mask 2.

Further, the support bar 3 is disposed to be corresponding to a gap between the first opening zone A1 and the second opening zone A2, or a gap between two adjacent first opening zones A1. So the support bars 3 can avoid shading the first opening zone A1 and the second opening zone A2 on the basis of providing a support function. The support bars 3 can be connected with the mask 2 by welding or other ways for enhancing the support strength for the mask 2.

The shadow bar 4 is disposed in the workspace D and located below the mask 2. The shadow bar 4 is not right under the mask 2, and here is just a description of the relative relationship between two planes where the both are located respectively. Namely, one plane, where the shadow bar 4 is located, is below the other plane, where the mask 2 is located. In the embodiment, in order to clearly describe the technical scheme of the present invention, only four shadow bars 4 are schematically depicted, and the four shadow bars 4 are parallel.

One shadow bar 4 is disposed to be corresponding to a gap between two adjacent masks 2 or a gap between the mask 2 and the external framework 1 for shading the gap and avoiding organic materials to pass through the gap and be evaporated on the array substrate. In the first direction, two ends of the shadow bar 4 are connected with the external framework 1. Specifically, in the embodiment, the two ends of the shadow bar 4 can be fixed on the external framework 1 by welding. In other embodiments of the present invention, the two ends of the shadow bar 4 can also be fixed on the external framework 1 by other ways. For example, the two ends of the shadow bar 4 can be fixed on the external framework 1 by screw. Wherein, the first direction is at an angle with the second direction. In the embodiment, the first direction is perpendicular to the second direction. The first direction refers to Y direction, and the second direction refers to X direction. That is to say, in the embodiment, the shadow bar 4 is parallel to the mask 2.

The support bar 3 and the shadow bar 4 can intersect to form a plurality of display limiting areas E, each of which is used to limit a shape of a display area of the array substrate. Specifically, multiple support bars 3 and multiple shadow bars 4 can intersect to form a plurality of gridding structures, each of which is one display limiting area E. The first opening zone A1 and the second opening A2 of the mask 2 are corresponding to at least one display limiting area E. Specifically, in the embodiment, at one end of the mask 2 with the second opening zone A2, each first opening zone A1 is corresponding to one display limiting area E, and each second opening zone Z2 is corresponding to one display limiting area E. In other embodiments, at one end of the mask 2 with the second opening zone A2, the first opening zone A1 and the second opening zone A2 are corresponding to one display limiting area E; but at other positions of the mask 2, the first opening zone A1 is corresponding to one display limiting area E.

The above is only the preferred embodiment of the present invention. It should be pointed out that for ordinary technicians in the technical field, without departing from the principles of the present invention, a number of improvements and embellishments can be made, which should also be regarded as the scope of protection of the present invention.

### INDUSTRIAL PRACTICABILITY

The subject of this application can be manufactured and used in industry and has industrial practicability.

What is claimed is:

1. A mask, comprising multiple first opening zones, at least one second opening zone and a frame enclosing the first opening zones and the second opening zone; in a first direction, the second opening zone being disposed on at least one end of the first opening zones; each first opening zone including at least one first evaporation zone, and the second opening zone including at least one second evaporation zone; the first evaporation zone having multiple first openings, the second evaporation zone having multiple second openings, and a density of the multiple first openings being greater than that of the multiple second openings; the first opening zone further including a first buffer zone surrounding the first evaporation zone, and the second opening zone further including a second buffer zone surrounding the second evaporation zone; the first buffer zone having multiple third openings, which are all-etched or semi-etched; the second buffer zone having multiple fourth openings, which are all-etched or semi-etched; the mask disposing one unetched zone between the first opening zone and the second opening zone, and further disposing one unetched zone between each two adjacent first opening zones.

2. The mask as claimed in claim 1, wherein the mask includes two second opening zones, in the first direction, the two second opening zones are disposed on two ends of the multiple first opening zones.

3. The mask as claimed in claim 1, wherein the second opening zone includes multiple second evaporation zones, and the second buffer zone surrounds the multiple second evaporation zones.

4. A mask, comprising at least one first opening zone, at least one second opening zone and a frame enclosing the first opening zone and the second opening zone; in a first direction, the second opening zone being disposed on at least one end of the first opening zone; the first opening zone including at least one first evaporation zone, and the second opening zone including at least one second evaporation zone; the first evaporation zone having multiple first openings, the second evaporation zone having multiple second openings, and a density of the multiple first openings being greater than that of the multiple second openings.

5. The mask as claimed in claim 4, wherein the mask comprises multiple first opening zones and two second opening zones, in the first direction, the two second opening zones are disposed on two ends of the multiple first opening zones.

6. The mask as claimed in claim 4, wherein the frame has a connection zone connected with an external device, and the second opening zone is located between the connection zone and the first opening zone.

7. The mask as claimed in claim 4, wherein the first opening zone further includes a first buffer zone surrounding the first evaporation zone, and the second opening zone further includes a second buffer zone surrounding the second evaporation zone.

8. The mask as claimed in claim 7, wherein the second opening zone includes multiple second evaporation zones, and the second buffer zone surrounds the multiple second evaporation zones.

9. The mask as claimed in claim 7, wherein the first buffer zone has multiple third openings, which are all-etched or semi-etched; and the second buffer zone has multiple fourth openings, which are all-etched or semi-etched.

10. The mask as claimed in claim 4, wherein the mask disposes one unetched zone between the first opening zone and the second opening zone; the mask further includes multiple first opening zones, and disposes one unetched zone between each two adjacent first opening zones.

11. A mask device, characterized in that, comprising:
an external framework, having a hollow workspace;
at least one mask as claimed in claim 4, in the first direction, two ends of the frame being connected with the external framework;
at least one support bar, being disposed in the workspace; in a second direction, two ends of the support bar being connected with the external framework for supporting the mask; and
at least one shadow bar, being disposed in the workspace and being corresponding to a gap between the mask and the external framework for shading the gap; in the first direction, two ends of the shadow bar being connected with the external framework; the support bar and the shadow bar intersecting to form a plurality of display limiting areas; the first opening zone and the second opening zone of the mask being corresponding to at least one display limiting area.

12. The mask device as claimed in claim 11, characterized in that, the mask device includes multiple masks and multiple shadow bars, and at least one shadow bar is corresponding to a gap between two adjacent masks for shading the gap.

13. The mask device as claimed in claim 11, characterized in that, the mask includes multiple first opening zones and multiple support bars; at least one support bar is corresponding to a gap between the first opening zone and the second opening zone, and at least another support bar is corresponding to a gap between two adjacent first opening zones.
